(19) United States
(12) Patent Application Publication
(10) Pub. No.: US 2007/0051968 A1
(43) Pub. Date: Mar. 8, 2007

(54) Nitride-based semiconductor light-emitting device and method of manufacturing the same

(76) Inventors: Shuichiro Yamamoto, Hiroshima (JP); Atsushi Ogawa, Hiroshima (JP); Masaya Ishida, Nara (JP); Takeshi Kamikawa, Hiroshima (JP)

Correspondence Address: HARNESS, DICKEY & PIERCE, P.L.C., P.O. BOX 8910, RESTON, VA, 20195, US

(21) Appl. No.: 10/556,907

(22) PCT Filed: Apr. 18, 2004
(86) PCT No.: PCT/JP04/08604

§ 371 Date: Nov. 15, 2005

(30) Foreign Application Priority Data
Jun. 30, 2003 (JP) 2003-187318

(51) Int. Cl. H01L 33/00

(52) U.S. Cl. 257/99; 257/98

(57) ABSTRACT

A nitride-based semiconductor light-emitting device having excellent reliability and long lifetime, and a method of manufacturing the same are provided. A nitride-based semiconductor light-emitting element chip, in which a nitride-based semiconductor layer and a first electrode are formed on a surface of an electrically conductive substrate and a second electrode is formed on a rear surface of the electrically conductive substrate, is mounted on a submount, and the submount having the nitride-based semiconductor light-emitting element chip mounted thereon is further mounted on a stem to form a nitride-based semiconductor light-emitting device.

### TECHNICAL FIELD

The present invention relates to a nitride-based semiconductor light-emitting device having high reliability and long lifetime even if it is used at high outputs, and a method of manufacturing the same.

### BACKGROUND ART

In recent years, development has been made to use a nitride-based semiconductor as a material of a short wavelength light-emitting element intended for a light-emitting diode (LED), a semiconductor laser and the like used in a semiconductor light-emitting device. The semiconductor light-emitting device used herein refers to a light-emitting element chip such as an LED chip or a semiconductor laser chip integrally mounted on a mount member serving as a supporting base of a heatsink. For example, a semiconductor laser chip mounted on a mount member is referred to as a semiconductor laser device. For the LED chip, a nitride-based semiconductor has already been in practical use. However, when the nitride-based semiconductor is used for a semiconductor laser chip, it is necessary to solve the problems of how to improve reliability and high temperature properties, how to provide high output, and others. A semiconductor laser device requires high efficiency in heat dissipation to prevent degradation of a light-emitting portion due to temperature rise in operation. Therefore, it is critical to mount a semiconductor laser chip on a supporting base such that high thermal conductivity is obtained.

Methods of mounting can roughly be divided into two categories; a junction-up method by which a chip having a layered body formed thereon is placed on a supporting base by allowing a substrate side of the chip to face the supporting base, and a junction-down method by which a chip having a layered body formed thereon is placed on a supporting base by allowing a grown layer side of the chip to face the supporting base. A junction-down structure is superior in heat dissipation efficiency because the distance between an active layer that generates a large amount of heat and the supporting base is short. However, its mount process is difficult to perform, thereby resulting in reduction in yield. In contrast, a junction-up structure is attained through a relatively easy mount process since the chip is mounted on a submount and then a stem by allowing an electrode structure formed on a rear surface of the substrate to face the submount. However, its heat dissipation efficiency is low because the distance between the active layer and the supporting base is large. Therefore, when an output of the semiconductor laser is increased, an amount of heat generated by the active layer is significantly increased, which adversely affects reliability and lifetime. To ensure heat dissipation properties and current-voltage properties of the light-emitting element, it is necessary to select a material suitable for a mount member such as a submount, a stem or a solder material, and an n-type electrode material. However, a mount member and a mount structure which have excellent heat dissipation properties and do not adversely affect the property of a light-emitting element have not yet been developed, and thus sufficient reliability and lifetime have not yet been achieved.

For a method of improving the property of an electrode in a semiconductor light-emitting device using an electrically conductive substrate, there is proposed, for example, a method of manufacturing a semiconductor light-emitting device which has a supporting base and a semiconductor light-emitting element having a layered body of a nitride-based semiconductor provided on a GaN substrate and mounted above the supporting base, including the steps of providing, on a side of the GaN substrate opposed to a layered body side, a first metal film made by a material that can make ohmic contact with the GaN substrate and serving as an N-type electrode, a second metal film made of a metal having a high melting point and serving as a barrier layer, and a third metal layer made of a material that can easily be mixed with solder, and placing the solder between the third metal layer and the supporting base (Patent Document 1). In this method, the electrode can make favorable ohmic contact with the GaN substrate, thereby the electrode property can be improved. However, the heat dissipation property thereof is insufficient for heat generated by the semiconductor light-emitting element when the semiconductor light-emitting device is used at high outputs, and thus satisfactory reliability and lifetime cannot be obtained.

There is also proposed a method of manufacturing a semiconductor light-emitting device such that a main surface of a semiconductor light-emitting element chip is made to be curved, and particularly convex, on the substrate side when seen from a functional layer having a nitride-based compound semiconductor formed on the substrate (Patent Document 2). In this method, the rate of defective products can be lowered by allowing a surface of the semiconductor light-emitting element chip to have a certain shape. However, the heat dissipation property thereof is insufficient for the heat generated by the semiconductor light-emitting element chip when the semiconductor light-emitting device is used at high outputs, and thus satisfactory lifetime cannot be obtained.

Patent Document 1: Japanese Patent Laying-Open No. 2002-134822

Patent Document 2: Japanese Patent Laying-Open No. 2003-31895

### DISCLOSURE OF THE INVENTION

Problems to be Solved by the Invention

An object of the present invention is to provide a nitride-based semiconductor light-emitting device which can solve the problems above and has excellent reliability and long lifetime even if it is used at high outputs, and a method of manufacturing the same.

Means for Solving the Problems

The present invention is a nitride-based semiconductor light-emitting device characterized in that a nitride-based semiconductor light-emitting element chip, in which a nitride-based semiconductor layer and a first electrode are formed in succession on a surface of an electrically conductive substrate and a second electrode having a conductivity type different from that of the first electrode is formed on a rear surface of the electrically conductive substrate, is mounted on a submount by allowing its second electrode side to face the submount and allowing a first solder material to be interposed therebetween, and the submount having the nitride-based semiconductor light-emitting element chip mounted thereon is mounted on a stem by allowing a second solder material to be interposed therebetween, and a method of manufacturing the same.

In the present invention, the semiconductor light-emitting device refers to a light-emitting element chip such as an LED chip or a semiconductor laser element chip integrally mounted on a mount member serving as a supporting base of a heatsink. For example, a semiconductor laser element chip mounted on a mount member is referred to as a semiconductor laser device. A mount member indicates a member on which a semiconductor light-emitting element chip is to be mounted directly, and refers to, for example, a submount; a stem, if a semiconductor light-emitting element chip is directly mounted on a supporting base without using a submount; a frame; or a package. The first electrode and the second electrode have different conductivity types, and the case in which the first electrode is p-type and the second electrode is n-type, and the case in which the first electrode is n-type and the second electrode is p-type are both included. A nitride-based semiconductor light-emitting device according to the present invention can ensure high reliability and long lifetime by mounting a nitride-based semiconductor light-emitting element chip on a submount and further on a stem to provide high mounting strength and excellent heat dissipation efficiency with respect to the heat generated by an active layer and its proximity.

Effects of the Invention

In the present invention, it is possible to manufacture a nitride-based semiconductor light-emitting device having excellent reliability and long lifetime even if it is used at high outputs, by providing a mount structure having high adhesion strength between the nitride-based semiconductor light-emitting element chip and the mount member, and excellent heat dissipation properties.

### BRIEF DESCRIPTION OF THE DRAWINGS

FIG. 1 is a cross section of a semiconductor laser device according to an embodiment of the present invention.

FIG. 2 is a schematic perspective view of the semiconductor laser device according to an embodiment of the present invention.

FIG. 3 is a cross section showing a structure of a laser element in the semiconductor laser device.

FIG. 4 is a cross section showing a laser structure of the semiconductor laser device.

### DESCRIPTION OF THE REFERENCE SIGNS

101 semiconductor laser element chip, 102 first solder material, 103 submount, 104 second solder material, 105 stem, 106 pin, 107 wire, 108 the entire stem, 201 electrically conductive substrate, 202 n-type GaN layer, 203 n-type cladding layer, 204 n-type light guide layer, 205 active layer, 206 carrier block layer, 207 p-type light guide layer, 208 p-type cladding layer, 209 p-type contact layer, 210 SiO₂ film, 211 first electrode, 212 second electrode.

### BEST MODES FOR CARRYING OUT THE INVENTION

A typical configuration of a nitride-based semiconductor light-emitting device according to the present invention will be described by taking a semiconductor laser device as an example. In some parts of the following description of the semiconductor laser device, a conductivity type of the electrode is limited to a p-type or an n-type. However, such a description is simply made to provide an embodiment to facilitate the understanding of the present invention, and is not intended to limit the conductivity type thereto.

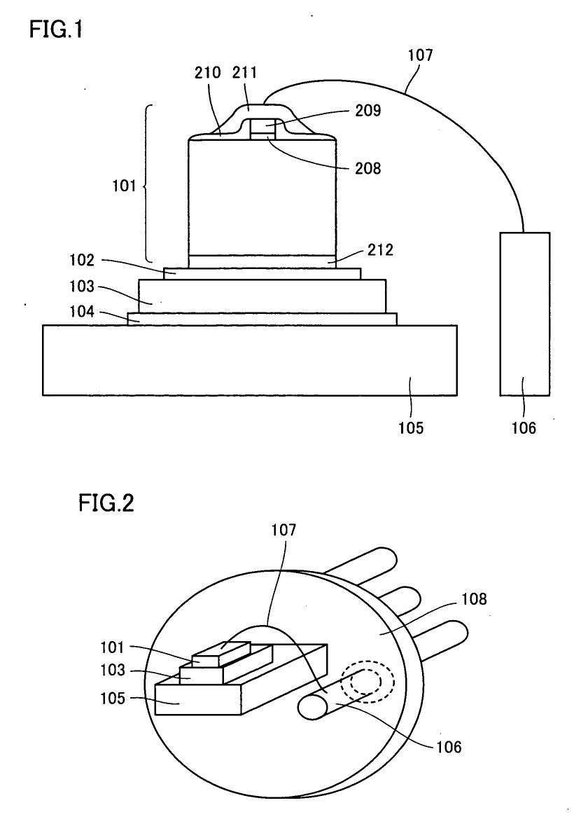

As shown in FIGS. 1 and 2, a nitride-based semiconductor laser element chip 101, in which a nitride-based semiconductor layer and a first electrode 211 are formed in succession on a surface of an electrically conductive substrate and a second electrode 212 is formed on a rear surface of the electrically conductive substrate, is mounted on a submount 103 by allowing second electrode 212 to face submount 103 and allowing a first solder material 102 to be interposed therebetween. The submount is further mounted on a stem 105 by allowing its submount side to face stem 105 serving as a supporting base and allowing a second solder material 104 to be interposed therebetween. Furthermore, a pin 106 of the stem is electrically connected to first electrode 211 via a wire 107 to form a semiconductor laser device. In the following, an embodiment of the present invention in a semiconductor laser device, which is a typical example of a nitride-based semiconductor light-emitting device according to the present invention, will be described.

<Manufacture of Semiconductor Laser Element Chip>

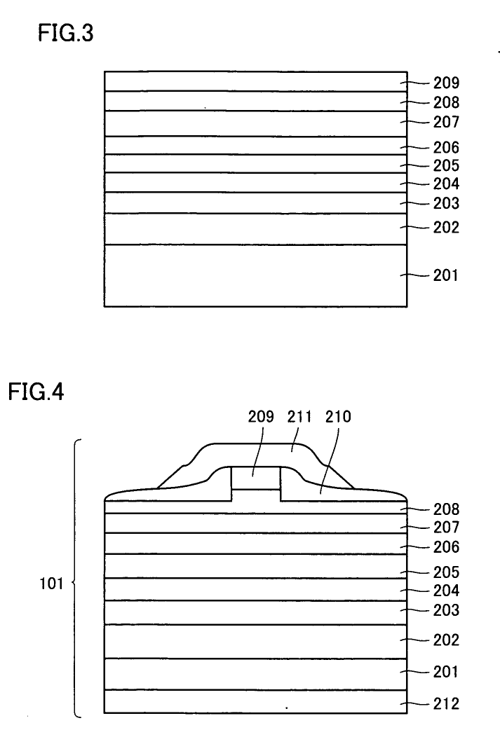

In FIG. 3, initially, an n-type GaN layer 202, an n-type cladding layer 203, an n-type light guide layer 204, an active layer 205, a carrier block layer 206, a p-type light guide layer 207, a p-type cladding layer 208, and a p-type contact layer 209, for example, are layered in succession to form a nitride-based semiconductor layer on an electrically conductive substrate 201 by a method generally used for manufacturing a semiconductor element such as an MOCVD method so that a laser element structure having the nitride-based semiconductor layer provided thereon is obtained.

In the present invention, an electrically conductive substrate is used for a substrate. With the use of the electrically conductive substrate, heat generated at an active layer in the nitride-based semiconductor layer and the proximity thereof is efficiently dissipated toward the mount member via the substrate. For the electrically conductive substrate used in the present invention, a material having high thermal conductivity is preferable. For example, sapphire generally used for a substrate on which a nitride-based semiconductor layer is to be grown is not preferable owing to its low thermal conductivity. The nitride-based semiconductor layer grown on the electrically conductive substrate has a thickness of approximately several micrometers, whereas the electrically conductive substrate has a thickness of several hundreds of micrometers even after it is ground and polished. Therefore, if the electrically conductive substrate has poor thermal conductivity, efficiency in heat propagation from the nitride-based semiconductor layer to the mount member via the substrate is degraded, resulting in that the heat dissipation efficiency of the semiconductor laser element is decreased.

Examples of an electrically conductive substrate having high thermal conductivity include gallium nitride (GaN), silicon carbide (SiC), zinc oxide (ZnO), and others. Among them, a nitride-based semiconductor substrate made of GaN and others can preferably be used. In this case, heat can efficiently be dissipated. In addition, the nitride-based semiconductor substrate has a lattice constant less different from that of the grown layer when compared with sapphire, which can improve crystallinity of the grown layer, and thus improve element properties and reliability. Moreover, if sapphire is made to form a substrate, for example, the element is inevitably configured to have a lateral structure in which an n-type electrode and a p-type electrode are placed on the top surface thereof, since sapphire is a non-conductor. In contrast, with the use of the nitride-based semiconductor substrate, the element can be configured to have a vertical structure as in the present invention because the nitride-based semiconductor substrate can be made electrically conductive by being doped. Therefore, the process of forming the element can be simplified.

A method of fabricating a semiconductor laser device will be described below. In FIG. 4, first electrode 211 is formed on the nitride-based semiconductor layer, and second electrode 212 is formed on the rear surface of the substrate so that a laser structure is fabricated. P-type contact layer 209 is etched into p-type cladding layer 208 by dry etching or the like, such that a stripe-like portion thereof having a width of 2 μm, for example, is left to form an optical waveguide. An SiO₂ film 210 is then evaporated thereonto as an insulating film. After the SiO₂ on a ridge is removed, Pd, Mo and Au, for example, are layered in succession to form first electrode 211 at p-type contact layer 209. As a substitute for the layered structure of Pd and Mo, it is possible to use a layer formed of a simple substance or a compound of at least one of Pd, Co, Cu, Ag, Ir, Sc, Au, Cr, Mo, La, W, Al, Tl, Y, La, Ce, Pr, Nd, Sm, Eu, Tb, Ti, Zr, Hf, V, Nb, Ta, Pt, and Ni. As a substitute of the Au layer, it is possible to use a layer formed of a simple substance or a compound of at least one of Au, Ni, Ag, Ga, In, Sn, Pb, Sb, Zn, Si, Ge, and Al.

Subsequently, the first electrode may be alloyed through electrode alloying. By the alloying, it is possible to form an electrode having favorable ohmic properties.

Thereafter, electrically conductive substrate 201 is ground and polished. Grinding is a process required to divide the fabricated semiconductor laser element into individual chips. The fabricated semiconductor laser element can easily be divided into chips by grinding the substrate and reducing its thickness. Polishing is a process required to remove a number of flaws generated on the rear surface of the substrate in grinding and planarize the same. If the rear surface of the substrate is not polished and an electrode is formed thereon, then adhesion strength is lowered, causing the electrode to peel off, and others.

Grinding can be performed by grinding the rear surface of the electrically conductive substrate by means of a grinder to approximately 200 μm. Polishing can be performed by planarizing the rear surface of the substrate by using diamond slurry or the like, and subjecting the same to a finish by an abrasive cloth and an abrasive such as alumina so that the polished surface is brought into a mirror-smooth state.

For the rear surface of the electrically conductive substrate after polishing, it is preferable to remove a damaged layer remaining thereon by preprocessing such as dry etching, and then form a second electrode thereon. By doing so, it is possible to form an electrode having favorable ohmic properties. For the conditions of dry etching, it is possible to apply, for example, a method of etching the surface of the electrically conductive substrate by 0.1-3.0 μm by an RIE processing in which halogen such as chlorine is used as a reactive gas, and other processing. Particularly if the surface of the electrically conductive substrate is etched by 0.5-3.0 μm, a damaged layer thereon can completely be removed and the substrate does not exhibit surface roughening caused by the RIE processing. By removing a damaged layer, it is possible to make favorable ohmic contact between the substrate and the electrode. Here, the use of a chlorine gas as a reactive gas is particularly preferable because the chlorine gas has an effect of modifying the surface of the electrically conductive substrate to improve its electrical conductivity.

On the rear surface of the electrically conductive substrate planarized in such a manner, second electrode 212 is formed. The second electrode preferably has an electrode structure made by a plurality of metal layers. If the element has a vertical structure as in the nitride-based semiconductor light-emitting device according to the present invention, and the second electrode is formed on the rear surface of the electrically conductive substrate, then the electrode is required to have excellent ohmic property as well as excellent adhesion with the mount member. Therefore, the electrode is allowed to have a layered structure made of, for example, a first layer serving as a metal that provides ohmic properties, a second layer serving as a barrier metal placed between the first layer and a third layer to prevent metals in both of the layers from mixing, and a third layer serving as a bonding metal, so that an electrode having satisfactory ohmic properties as well as satisfactory mounting properties can be obtained. Each of the layers above may be formed of a single layer or multiple layers. A layer having another function may further be included in each of the layers above as long as each of the layers has a function described above.

The first layer serves as a layer for providing favorable ohmic properties to the electrode, and is allowed to have a layered structure including a layer using at least one of Hf, Co, Cu, Ag, Ir, Sc, Au, Cr, Mo, La, Ce, Pr, Nd, Sm, Eu, Tb, Zr, Ti, V, Nb, Ta, and Pt as a simple substance or a compound, and a layer using at least one of Al, Au, Ni, Ag, Ga, In, Sn, Pb, Sb, Zn, Si, and Ge as a simple substance or a compound. Particularly if the layered structure includes two or more types of metal selected from Ti, Hf and Al, excellent ohmic properties can be provided, and HfAl is more preferably used. For HfAl, it is possible to made favorable ohmic contact by forming Hf and Al in succession and then alloying them through electrode alloying. In this case, it is preferable for Hf and Al to have thicknesses of 1-30 nm and 30-500 nm, respectively, because high bonding strength is provided at an interface between the substrate and the electrode. In addition to the method of using Hf and Al, a method of using a structure formed of a single layer or a layered structure formed of two or more layers, of a compound containing Hf, Al and GaN, or the like may be used. Electrode alloying can be performed under the temperature condition of 450-700° C., particularly 500° C., in a vacuum or an inert gas such as N₂.

The second layer serves as a barrier metal, and the third layer serves as a layer for bonding the electrode metal, which provides favorable ohmic properties, to the submount in a manner where high adhesion is obtained. For the second layer, it is preferable to use a two-layered structure made of Mo and Pt. For the third layer, it is preferable to use Au.

The second layer serves as a barrier layer having an effect of preventing degradation in ohmic property caused by the contact between the first layer and the third layer and the alloying of these layers. The second layer preferably has a layered structure made of Mo and Pt in this order. Since Mo is a metal having a high melting point, it is less likely to diffuse. Therefore, Mo provides an effect of preventing the alloying of Al in the first layer and Au in the third layer caused by the contact between them. A small amount of Pt can diffuse into Mo, and into Au in the third layer, which has an effect of improving adhesion strength between the first layer and the second layer, and between the second layer and the third layer.

Mo preferably has a thickness of 5 nm-100 nm because another metal cannot diffuse in the Mo layer.

For the third layer, it is preferable to use Au having high affinity with a solder material. Since the use of Au allows a semiconductor laser element to be mounted on the submount in a manner where high adhesion is obtained, the peel-off of the electrode can effectively be prevented. If Au has a thickness of 50-750 nm, particularly 100-500 nm, it serves as a bonding layer in a favorable manner.

To form an electrode of a second conductivity type, an EB evaporation method can preferably be used. Alternatively, such an electrode may be formed by, for example, sputtering.

An end face of the laser can be made by cleavage in the formed laser structure by setting the resonator length, for example, at 300-1500 μm. A method of forming an end face of the laser is not limited to cleavage. By any of known methods including etching and the like, a strip-like piece on which a plurality of semiconductor laser elements are placed is obtained.

The piece is divided into semiconductor laser element chips by a known method such as a scribing method, a dicing method, and a laser scribing method. In the scribing method, for example, a scribe line is formed from the rear surface side of the electrically conductive substrate, and the electrically conductive substrate is divided along the scribe line. As such, a semiconductor laser element chip is completed.

<Mounting>

Mounting is performed through two processes including a submount process for mounting the semiconductor laser element chip on a submount, and a mount process for further mounting the submount on a stem, so that the semiconductor laser device is manufactured. In the present invention, a mount structure preferably uses a submount because heat generated at the semiconductor laser element is efficiently removed to ensure reliability. In this case, heat generated at an active layer of the semiconductor laser element and the periphery thereof is transmitted to the electrically conductive substrate. Since the electrically conductive substrate is mounted on a submount, which is made of a material having high thermal conductivity, by allowing a solder material to be interposed therebetween, the heat transmitted to the electrically conductive substrate is efficiently transmitted to the submount via the solder material.

A material of the submount preferably has a thermal conductivity higher than that of the electrically conductive substrate. From this viewpoint, AlN can preferably be used. Any state of AlN such as a single crystal, polycrystal, or amorphous state may be used as long as AlN has sufficient strength, and AlN may have a thickness of approximately 100-750 μm.

In the submount process and the mount process, a solder material is used to bond the semiconductor laser element chip to the submount, and the submount to the stem. Here, the solder material is an alloy or a metal of a simple substance used for bonding. A bonding method is not particularly limited, and is implemented by so-called die bonding as follows: in the submount process, for example, a solder material is provided on a submount in advance, and a semiconductor laser element chip is placed on a prescribed position of the solder. Thereafter, the submount is heated to melt the solder material. In this state, a pressure is applied to the semiconductor laser element chip to bond the same to the submount, and then solidify the solder material by lowering the temperature. According to the method, the semiconductor laser element chip can be bonded to the submount in a manner where high thermal conductivity is obtained. Also in the mount process, bonding can be performed with a method similar to that of the submount process.

Referring to FIG. 1, a first solder material 102 is initially formed to have a thickness of approximately 3 μm at a prescribed position of submount 103. Semiconductor laser element chip 101 is placed on first solder material 102 by allowing its second electrode 212 side to face first solder material 102. Submount 103 is heated to a temperature equal to or above the melting point of first solder material 102 to melt the solder material so that semiconductor laser element chip 101 is bonded to submount 103. The temperature is lowered to solidify first solder material 102.

A second solder material 104 is then formed at a prescribed position of stem 105.

Submount 103 having the semiconductor laser element formed thereon as described above is placed on second solder material 104 by allowing its submount side to face second solder material 104. Submount 103 is heated to a temperature equal to or above the melting point of second solder material 104 to melt second solder material 104 so that submount 103 is bonded to stem 105. The temperature is lowered to solidify the soldering agent.

For the first solder material, Au_{0.8}Sn_{0.2} can be used. In addition to AuSn, SnSb, SnAg, SnAgCu, InSn, InAg, In, or the like can also be used. If AuSn is used, adhesion between the AlN submount and the semiconductor laser element chip can significantly be increased.

For the second solder material, it is preferable to use a material capable of firmly bonding the AlN submount to the stem. For example, a material including at least one of SnAgCu, AuSn, SnSb, SnAg, SnSb, InSn, InAg, Sn, and In can preferably be used. In particular, SnAg_{0.03}Cu_{0.005} and In can preferably be used.

From the viewpoint of mounting strength, it is preferable that the second solder material has a melting point approximately equal to or below that of the first solder material.

By using various known methods, another layer may be interposed between the submount and the solder material, and between the stem and the solder material. Examples of the layer to be interposed therebetween include a layer for improving adhesion between the submount or the stem and the solder material, a layer for suppressing reaction between the submount or the stem and the solder material, and the like. These layers may be a single layer or a layered structure made of a plurality of layers.

<Bonding>

Thereafter, a pin 106 is connected to first electrode 211 of the semiconductor laser element chip by a wire 107 so that the semiconductor laser element chip is electrically connected to the stem. For wire 107, a thin wire made of Au is preferably used, and bonding is performed with a wire bonding device. Lastly, a cap is attached to the stem with an inert gas such as a nitrogen gas preferably encapsulated therein to suppress degradation in element property.

With the above-described method, a semiconductor laser device serving as an example of the present invention is completed. Embodiments of the present invention in manufacturing the semiconductor laser device will now be described.

### First Embodiment

<Manufacture of Semiconductor Laser Element Chip>

A GaN substrate serving as electrically conductive substrate 201 is introduced into an MOCVD device, in which N₂ and ammonia (NH₃) are allowed to flow at flow rates of 5 L/min, respectively, and the temperature is raised to 1050° C. After the temperature rise, H₂ is used as a substitute of N₂ serving as a carrier gas. Trimethyl gallium (TMG) and silane (SiH₄) are introduced at flow rates of 100 μmol/min and 10 nmol/min, respectively, to grow n-type GaN layer 202 having a thickness of 4 μm. Thereafter, the flow rate of TMG is adjusted to 50 μmol/min and trimethyl aluminium (TMA) is introduced at a flow rate of 40 μmol/min, so that Al_{0.1}Ga_{0.9}N serving as n-type cladding layer 203 is grown to have a thickness of 0.5 μm. After the Al_{0.1}Ga_{0.9}N is grown, the supply of TMA is ceased, and the flow rate of TMG is adjusted to 100 μmol/min, so that GaN serving as n-type light guide layer 204 is grown to have a thickness of 0.1 μm. Afterwards, the supply of TMG and SiH₄ is ceased. N₂ is used again as a substitute of H₂ serving as a carrier gas, and the temperature is lowered to 700° C. Trimethyl indium (TMI), which is a raw material of indium, and TMG are introduced at flow rates of 10 μmol/min and 15 mol/min, respectively, so that a barrier layer made of In_{0.05}Ga_{0.95}N is grown to have a thickness of 4 nm. Thereafter, the supply of TMI is increased to 50 μmol/min to grow a well layer made of In_{0.2}Ga_{0.8}N with a thickness of 2 nm. Three well layers in total are grown with the similar method above to grow active layer 205 having a structure of a multiple quantum well (MQW) in which each of the three well layers is sandwiched by two of four barrier layers in total. After the MQW is completely grown, the supply of TMI and TMG is ceased and the temperature is raised again to 1050° C. H₂ is used again as a substitute of N₂ serving as a carrier gas, and then TMG, TMA and biscyclopentadienyl magnesium (Cp₂Mg), which is a raw material of p-type doping, are introduced at flow rates of 50 μmol/min, 30 μmol/min, and 10 nmol/min, respectively, so that Al_{0.2}Ga_{0.8}N serving as p-type carrier block layer 206 is grown to have a thickness of 20 nm. After the carrier block layer is completely grown, the supply of TMA is ceased and the supply of TMG is adjusted to 100 μmol/min so that GaN serving as p-type light guide layer 207 is grown to have a thickness of 0.1 μm. Afterwards, the supply of TMG is adjusted to 50 μmol/min and TMA is introduced at a flow rate of 40 μmol/min so that Al_{0.1}Ga_{0.9}N serving as p-type cladding layer 208 is grown to have a thickness of 0.4 μm. Lastly, the supply of TMG is adjusted to 100 μmol/min and the supply of TMA is ceased so that GaN serving as p-type contact layer 209 is grown to have a thickness of 0.1 μm. The supply of TMG and Cp₂Mg is then ceased and the temperature is lowered. The substrate is removed from the MOCVD device at room temperature, and the laser element structure is completed.

The laser element structure removed from the MOCVD device is used to fabricate a laser structure. Initially, p-type contact layer 209 is etched into p-type cladding layer 208 with a dry etching device such that a stripe-like portion thereof having a width of 2 μm is left to form an optical waveguide. SiO₂ film 210 serving as an insulating film is then evaporated thereonto. After the SiO₂ on a ridge is removed, Pd, Mo and Au are evaporated in succession onto p-type contact layer 209 to have thicknesses of 15 nm, 15 nm, and 200 nm, respectively, to form a p-type electrode serving as first electrode 211. After the p-type electrode is fabricated, it is subjected to electrode alloying in a vacuum at 500° C. for 10 minutes.

The GaN substrate serving as electrically conductive substrate 201 is then ground and polished. Initially, a grinder is used to grind the rear surface of the GaN substrate to a thickness of approximately 200 μm. The ground rear surface of the GaN substrate is then planarized with diamond slurry, and subjected to a finish by using an abrasive cloth and alumina serving as an abrasive, so that the surface thereof is brought into a mirror-smooth state.

In addition, an RIE processing using chlorine plasma is performed on the rear surface of the GaN substrate. The RIE processing is performed under the conditions that the pressure is 45 mtorr and the flow rate of chlorine is 80 ccm. The polished plane of the rear surface of the GaN substrate is dry-etched by approximately 1 μm in depth.

An n-type electrode serving as second electrode 212 is then formed on the rear surface of the GaN substrate. An EB evaporation device is used to form the electrode. Initially, to form an ohmic layer, Hf and then Al are evaporated to have thicknesses of 5 nm and 150 nm, respectively, and subjected to electrode alloying in a vacuum at 500° C. for three minutes so that the metals of the electrode and the GaN substrate are partially alloyed to be a first layer. On the first layer, Mo and Pt are layered in succession to have thicknesses of 30 nm and 15 nm, respectively, to form a barrier metal layer serving as a second layer. Further onto the second layer, Au is evaporated to have a thickness of 250 nm to form a bonding metal layer serving as a third layer.

With the above-described method, a laser structure in which semiconductor laser element is mounted on the GaN substrate is fabricated. The laser structure is then divided into a plurality of chips by a scribing method. By forming a scribe line from the rear surface side of the GaN substrate and applying force to the substrate, the semiconductor laser element is divided along the scribe line into individual semiconductor laser element chips.

<Mounting>

The semiconductor laser element chip is then mounted on a supporting base. Mounting is performed through two processes including a submount process for mounting the semiconductor laser element chip on a submount, and a mount process for placing the submount on a stem that serves as a supporting base.

In the submount process, Au_{0.8}Sn_{0.2} solder serving as first solder material 102 is formed by an EB evaporation method to have a thickness of 3 μm at a prescribed position of submount 103 made of AlN. The semiconductor laser element chip is placed on the Au_{0.8}Sn_{0.2} solder in an aligned manner by allowing second electrode 212 to face the Au_{0.8}Sn_{0.2} solder. In this state, the submount is heated to 300° C. to melt the first solder material. A pressure is applied to the semiconductor laser element chip to bond and fix the same to the submount. Thereafter, the temperature is lowered to solidify the first solder material, and the submount process is completed.

In the mount process, submount 103 is bonded to stem 105 serving as a supporting base of the semiconductor device. Initially, SnAg_{0.03}Cu_{0.005} solder, which has a foil-like shape with a thickness of approximately 10 μm, is placed at a prescribed position of the stem to serve as second solder material 104. On the SnAg_{0.03}Cu_{0.005} solder, the submount having the semiconductor laser element chip mounted thereon is placed in an aligned manner by allowing the submount to face the SnAg_{0.03}Cu_{0.005} solder. The temperature is then raised to 300° C. to melt the SnAg_{0.03}Cu_{0.005} solder. A pressure is applied to the submount having the semiconductor laser element chip mounted thereon to bond the submount to the stem. Lastly, the temperature is lowered to solidify the SnAgCu solder to complete the mount process.

With the above-described method, it is possible to mount the AlN submount and the semiconductor laser element chip on a prescribed position of the stem.

<Bonding>

A p-type electrode wire made of a thin wire of Au is used as wire 107. Pin 106 of the stem is connected to first electrode 211 with a wire bonding device. Lastly, a cap is attached to the stem with a nitrogen gas encapsulated thereinto. With the above-described method, the semiconductor laser device is completed.

<Property Evaluation>

For fifty semiconductor laser element chips obtained by dividing the semiconductor laser element mounted on the same wafer according to the method of the first embodiment, threshold currents before and after the mounting were compared. For the comparison, an average of the threshold current values before the mounting and an average of the threshold current values after the mounting were calculated with respect to the fifty semiconductor laser element chips. For the threshold current values after the mounting, values of two semiconductor laser element chips having extremely poor element properties due to initial failure were excluded from the calculation of an average. The element properties refer to a threshold current, and a driving current and a driving voltage at 30 mW.

Average threshold current values of the semiconductor laser element chips before and after the mounting were 41 mA and 37 mA, respectively, showing that the threshold current was slightly lowered after the mounting. It seems that by mounting the semiconductor laser element chips on the supporting bases, heat generated by the semiconductor laser elements was dissipated more efficiently and thus the threshold currents were lowered. Except for the two semiconductor laser element chips suffering from initial failure, forty-eight chips exhibited no degradation in element property, which allows the chips to be mounted on the supporting bases with high yields.

The fabricated semiconductor laser devices were then introduced into an aging device and subjected to the lifetime test. In the lifetime test, a time period required for a driving current at an atmospheric temperature of 60° C. and at an output of 30 mW to increase by a factor of 1.5 was specified as a lifetime. Four out of forty-eight semiconductor laser devices subjected to the lifetime test exhibited a failure, which seemed to be initial degradation. Except for the ones exhibiting initial degradation, there were no semiconductor laser devices whose driving currents increased by a factor of 1.5 during the lifetime test of 1000 hours. It was recognized that the lifetime at 60° C. and at 30 mW was at least 1000 hours.

### Second Embodiment

In this embodiment, SnAg_{0.03}Cu_{0.005} serving as second solder material 104 is transferred to the stem in advance.

Initially, a submount step for mounting a semiconductor laser element chip on a submount is performed according to the method of the first embodiment. Submount 103 having the semiconductor laser element chip mounted thereon is then mounted on stem 105. At this time, SnAgCu serving as second solder material 104 has already been transferred to the stem in advance. A method of transferring SnAg_{0.03}Cu_{0.005} to the stem is implemented as follows: a Teflon (R) tape having a length of approximately 500 nm and a width of approximately 500 μm is initially prepared. SnAg_{0.03}Cu_{0.005} is then evaporated to have a thickness of approximately 8 μm onto the Teflon (R) tape. Thereafter, the Teflon (R) tape to which the SnAg_{0.03}Cu_{0.005} solder is attached is aligned with stem 105. After the alignment, ultrasonic vibration of approximately 80 kHz is applied to the solder through the Teflon (R) tape, which makes it possible to transfer the SnAg_{0.03}Cu_{0.005} solder having a length of 500 μm, a width of 500 μm, and a thickness of 10 μm to stem 105.

Submount 103 is then bonded to stem 105. The submount having the semiconductor laser element chip mounted thereon is placed on the transferred SnAg_{0.03}Cu_{0.005} solder in an aligned manner by allowing the submount to face the SnAg_{0.03}Cu_{0.005} solder. Subsequently, the temperature is raised to 300° C. to melt the SnAg_{0.03}Cu_{0.005} solder and a pressure is applied to the submount having the semiconductor laser element chip mounted thereon to bond the submount to the stem. Lastly, the temperature is lowered to solidify the SnAg_{0.03}Cu_{0.005} solder to complete the mount process.

With the above-described method, submount 103 made of AlN, and semiconductor laser element chip 101 are mounted on a prescribed position of stem 105, and bonding is then performed as in the first embodiment to complete the semiconductor laser device.

For the semiconductor laser devices obtained by the above-described method, the properties thereof were evaluated as in the first embodiment.

The result shows that although three out of fifty semiconductor laser element chips exhibited failure, the remaining forty-seven semiconductor laser element chips had threshold currents of 43 mA and 40 mA before and after the mounting, respectively. Therefore, it was recognized that properties after the mounting were favorable.

In the lifetime test of the forty-seven semiconductor laser devices on which the above-described forty-seven semiconductor laser element chips free of failure were respectively mounted thereon, four semiconductor laser devices exhibited failure due to initial degradation. However, none of the remaining forty-three devices showed that a driving current after 1000 hours exceeded 1.5 times of an initial driving current. Therefore, it was recognized that the devices had a lifetime of at least 1000 hours.

### Third Embodiment

In the present embodiment, In is used as the second solder material, and In is transferred to the stem.

According to the method in the first embodiment, a submount process for placing semiconductor laser element chip 101 on submount 103 is performed. The submount having the semiconductor laser element chip mounted thereon is then mounted on stem 105. At this time, In has already been transferred to the stem in advance. A method of transferring In to the stem is described below.

A Teflon (R) tape having a length of 500 nm and a width of 500 μm is prepared. In is evaporated onto the Teflon (R) tape to have a thickness of approximately 10 μm. Thereafter, the Teflon (R) tape having the In solder attached thereto is aligned with stem 105. After the alignment is completed, ultrasonic vibration of approximately 80 kHz is applied to the solder through the Teflon (R) tape so that the In solder having a length of 500 μm, a width of 500 μm, and a thickness of 10 μm is transferred to the stem.

Submount 103 is then bonded to stem 105. The submount having semiconductor laser element chip 101 mounted thereon is placed on the transferred In solder in an aligned manner by allowing the submount to face the In solder. Subsequently, the temperature is raised to 300° C. to melt the In solder. A pressure is applied to the submount having the semiconductor laser element chip mounted thereon to bond the submount to the stem. Lastly, the temperature is lowered to solidify the In solder to complete the mount process.

With the above-described method, the AlN submount and the semiconductor laser element chip are mounted on a prescribed position of the stem. Afterwards, bonding is performed as in the first embodiment to complete the semiconductor laser device.

For the semiconductor laser devices obtained by the above-described method, the properties thereof were evaluated as in the method similar to that of the first embodiment.

When fifty semiconductor laser element chips were mounted, three of them exhibited degradation due to initial failure. The remaining forty-seven semiconductor laser element chips had thresholds of 42 mA and 39 mA before and after the mounting, respectively.

For the lifetime test of the semiconductor laser devices on which the above-described forty-seven semiconductor laser element chips were respectively mounted thereon, four devices exhibited failure due to initial degradation. None of the remaining forty-three devices showed that a driving current after 1000 hours exceeded 1.5 times of an initial driving current. Therefore, it was recognized that the devices had a lifetime of at least 1000 hours.

Although the present invention has been described and illustrated in detail, it is clearly understood that the same is by way of illustration and example only and is not to be taken by way of limitation, the spirit and scope of the present invention being limited only by the terms of the appended claims.

### INDUSTRIAL APPLICABILITY

In the present invention, it is possible to manufacture a nitride-based semiconductor light-emitting device having excellent reliability and long lifetime properties even if it is used at high outputs, by providing a mount structure having high adhesion strength between the nitride-based semiconductor light-emitting element chip and the mount member and excellent heat dissipation properties.

1. A nitride-based semiconductor light-emitting device, comprising a nitride-based semiconductor light-emitting element chip formed on an electrically conductive substrate, and a submount, solder, and a stem each serving as a mount member identified as a supporting base for mounting the nitride-based semiconductor light-emitting element chip, said submount being made of a material having a thermal conductivity highger than that of a material used to form said electrically conductive material, wherein
said nitride-based semiconductor light-emitting element chip, in which a nitride-based semiconductor layer and a first electrode are formed in succession on a surface of the electrically conductive substrate and a second electrode having a conductivity type different from that of the first electrode is formed on a rear surface of the electrically conductive substrate, is mounted on the submount by allowing its second electrode side to face the submount and allowing a first solder material to be interposed therebetween, and said submount having said nitride-based semiconductor light-emitting element chip mounted thereon is further mounted on the stem by allowing its submount side to face the stem and allowing a second solder material to be interposed therebetween.

2. The nitride-based semiconductor light-emitting device according to claim 1, wherein said submount is made of AlN.

3. The nitride-based semiconductor light-emitting device according to claim 1, wherein said first solder material is made of AuSn, and said second solder material is made of one of SnAgCu and In.

4. The nitride-based semiconductor light-emitting device according to claim 1, wherein said electrically conductive substrate is an n-type nitride-based semiconductor substrate.

5. The nitride-based semiconductor light-emitting device according to claim 1, wherein said second electrode is made by forming on the electrically conductive substrate three layers including a first layer which is a metal layer made of a single layer or a plurality of layers, or a metal layer having a plurality of layers mixed therein and makes it possible to form an ohmic electrode on the electrically conductive substrate, a second layer which is a metal layer serving as a barrier metal and made of a single layer or a plurality of layers, and a third layer which is a metal layer made of a single layer or a plurality of layers and having affinity with said first solder material, in this order.

6. The nitride-based semiconductor light-emitting device according to claim 1, wherein said second electrode has a first layer containing at least two types of metal selected from Ti, Hf and Al, a second layer having a layered structure formed by Mo and Pt in this order, and a third layer using Au.

7. A method of manufacturing a nitride-based semiconductor light-emitting device, wherein when said second electrode is formed, said electrically conductive substrate is dry-etched as preprocessing to manufacture the nitride-based semiconductor light-emitting device according to claim 1.
